(19) United States
(12) Patent Application Publication
(10) Pub. No.: US 2015/0364422 A1
(43) Pub. Date: Dec. 17, 2015

(54) FAN OUT WAFER LEVEL PACKAGE USING SILICON BRIDGE

(71) Applicant: Apple Inc., Cupertino, CA (US)

(72) Inventors: Jun Zhai, San Jose, CA (US); Kunzhong Hu, Cupertino, CA (US)

(21) Appl. No.: 14/497,495

(22) Filed: Sep. 26, 2014

Related U.S. Application Data
(60) Provisional application No. 62/011,840, filed on Jun. 13, 2014.

(51) Int. Cl. H01L 23/538; H01L 23/31; H01L 21/56; H01L 25/00; H01L 21/768; H01L 23/00; H01L 25/18

(52) U.S. Cl. CPC H01L 23/5381; H01L 24/81; H01L 23/3178; H01L 24/08; H01L 25/18; H01L 25/50; H01L 21/768; H01L 21/563; H01L 21/568; H01L 23/5386; H01L 24/03; H01L 2924/381; H01L 2224/02331; H01L 2224/0239; H01L 2924/1431; H01L 2924/1434

(57) ABSTRACT

A semiconductor device package includes a logic die coupled to a memory die in a side-by-side configuration on a redistribution layer (e.g., the logic die and the memory die are substantially adjacent). A silicon bridge may be used to interconnect the logic die and the memory die. The silicon bridge may be positioned between the die and the redistribution layer. The silicon bridge and the redistribution layer may be coupled to the lower (active) surfaces of the logic die and the memory die. The package may be formed using a wafer level process that forms a plurality of packages simultaneously.

### PRIORITY CLAIM

This patent claims priority to U.S. Provisional Patent Application No. 62/011,840 to Zhai et al., entitled “FAN OUT WAFER LEVEL PACKAGE USING SILICON BRIDGE”, filed Jun. 13, 2014, which is incorporated by reference in its entirety.

### BACKGROUND

1. Technical Field

Embodiments described herein relate to semiconductor packaging and methods for packaging semiconductor devices. More particularly, the embodiments described herein relate to a package with a logic die and to a memory die interconnected inside a semiconductor device package.

2. Description of Related Art

The semiconductor industry continues to develop semiconductor packages to have lower cost, higher performance, increased integrated circuit density, and increased package density. Logic die (e.g., system on a chip (“SoC”)) and/or memory die continue to become more highly integrated, which requires increased interconnection density. Thus, interconnect pitch is being reduced further and further to very fine or ultra fine levels.

Memory die are also continually being placed closer and closer to the logic die to reduce channel length. The increasing demand of memory bandwidth presents selected challenges to the signal integrity of memory channels within semiconductor packages. In some cases, two or more memory die are stacked to increase memory capacity in a package.

In some application configurations, the memory die is placed next to the logic die. For example, the memory die and the logic die may be in a side-by-side configuration with the memory die substantially adjacent to the logic die (e.g., the die are directly next to each other on a surface with only a small gap (if any) between the die). In such configurations, certain semiconductor device packages have thin profile and high interconnect density requirements that do not allow the use of traditional interconnection approaches between the die. For example, wire bonding interconnection, substrate interconnection, or post fabrication redistribution layer (RDL) interconnection may not be suitable for providing a high interconnect density while maintaining a desired thin profile in the semiconductor device package.

### SUMMARY

In certain embodiments, a semiconductor device package includes a logic die coupled to a substantially adjacent memory die (e.g., they are in a side-by-side configuration). The logic die and the memory die may be coupled (interconnected) with a silicon bridge. The silicon bridge may be coupled to the lower (active) surfaces of the logic die and the memory die. In certain embodiments, the silicon bridge is coupled to the logic die and the memory die using terminals that couple to patterned connections (traces) in the silicon bridge that have a very fine interconnect trace pitch (e.g., the traces have an interconnect trace pitch of at most about 1 μm).

In certain embodiments, the logic die and the memory die (with the interconnecting silicon bridge between them) are coupled to a redistribution layer (RDL). In some embodiments, the active (lower) surfaces of the die are coupled to the RDL. The silicon bridge may be positioned (located) between the lower surfaces of the die and the RDL. In some embodiments, the silicon bridge is located in a recess in the RDL. In certain embodiments, the RDL couples the logic die and/or the memory die to terminals (e.g., a ball grid array) on a lower surface of the RDL through routing in the RDL.

In certain embodiments, the logic die, the memory die, and the silicon bridge are at least partially encapsulated in an encapsulant. The encapsulant may be present between the die to maintain separation between the die. When the package is used as a discrete package, the encapsulation may enclose the die and the silicon bridge. When the package is used as one package in a PoP package (e.g., a bottom package), one or more vias in the encapsulant may coupled the RDL to another package (e.g., a top package) in the PoP package.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a cross-sectional representation of a logic die and a memory die.

FIG. 2 depicts a cross-sectional representation of a logic die and a memory die coupled to a carrier.

FIG. 3 depicts a cross-sectional representation of a logic die and a memory die interconnected with a silicon bridge.

FIG. 4 depicts a cross-sectional representation of a logic die, a memory die, and a silicon bridge in an encapsulant on a carrier.

FIG. 5 depicts a cross-sectional representation of a logic die, a memory die, and a silicon bridge in an encapsulant.

FIG. 6 depicts a cross-sectional representation of an embodiment of a semiconductor device package that includes a logic die, a memory die, a silicon bridge, and an RDL.

FIG. 7 depicts a cross-sectional representation of an embodiment of a plurality of logic die and memory die coupled with silicon bridges and formed on a wafer level.

FIG. 8 depicts a cross-sectional representation of an embodiment of a plurality of packages formed on a wafer level.

FIG. 9 depicts a cross-sectional representation of an embodiment of two packages formed using a wafer level process after singulation of the packages.

FIG. 10 depicts a cross-sectional representation of an embodiment of a package with vias through an encapsulant.

FIG. 11 depicts a cross-sectional representation of an embodiment of a semiconductor device package that includes a logic die, a memory die, a silicon bridge, and an RDL with the silicon bridge in a recess in the RDL.

While the embodiments described in this disclosure may be susceptible to various modifications and alternative forms, specific embodiments thereof are shown by way of example in the drawings and will herein be described in detail. The drawings may not be to scale. It should be understood that the drawings and detailed description thereto are not intended to limit the embodiments to the particular form disclosed, but to the contrary, the intention is to cover all modifications, equivalents and alternatives falling within the spirit and scope of the appended claims.

### DETAILED DESCRIPTION OF EMBODIMENTS

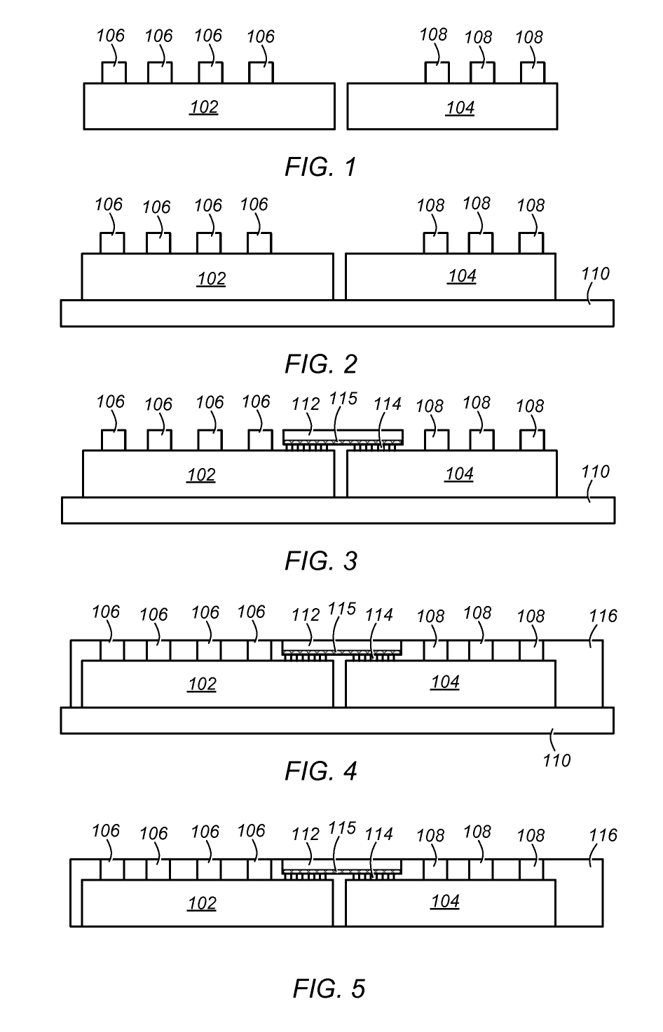

FIGS. 1-6 depict cross-sectional representations of an embodiment of a simplified process flow for forming a semiconductor device package. FIG. 1 depicts a cross-sectional representation of logic die 102 and memory die 104. Logic die 102 may be, for example, a system on a chip (“SoC”). In some embodiments, logic die 102 is a flip chip logic die. In certain embodiments, memory die 104 is a DDR (double data rate) die (e.g., an 8 GB DDR die). In some embodiments, memory die 104 is a flip chip memory die. In some embodiments, memory die 104 is a discrete memory die. In some embodiments, memory die 104 includes two or more memory die (e.g., vertically stacked memory die).

In certain embodiments, terminals 106 are formed on logic die 102 and terminals 108 are formed on memory die 104. Terminals 106 and 108 may be formed on active sides of logic die 102 and memory die 104, respectively. Terminals 106 and terminals 108 may be formed on their respective die while the die are on their original substrate or wafer (e.g., the substrate the die are formed on such as a silicon wafer). In certain embodiments, terminals 106, 108 are formed using wafer plating processes known in the art. Terminals 106, 108 may include copper, aluminum, or other suitable conductive materials. In some embodiments, terminals 106, 108 are solder-coated or Sn-coated. In certain embodiments, terminals 106, 108 are C4 bumps. In some embodiments, terminals 106, 108 include fan out connections and/or power delivery connections for die 102, 104.

In certain embodiments, logic die 102 and memory die 104 are coupled (e.g., transferred) to carrier 110, as shown in FIG. 2. Carrier 110 may be any carrier suitable for supporting and carrying a thin substrate. Carrier 110 may be, for example, a temporary substrate for a thin substrate made of silicon, glass, or steel. While the process flow embodiments depicted in FIGS. 1 and 2 show terminals 106, 108 being formed on die 102, 104, respectively, before the die are coupled to carrier 110, it is to be understood that the terminals may also be formed while the die are on the carrier.

As shown in FIG. 2, logic die 102 and memory die 104 may be coupled in a side-by-side configuration with some space between the die. Thus, logic die 102 and memory die 104 are substantially adjacent each other with some space separating side surfaces of the die. In certain embodiments, silicon bridge 112 is coupled to logic die 102 and memory die 104, as shown in FIG. 3. In certain embodiments, silicon bridge 112 is coupled to (e.g., directly attached to) the active sides of logic die 102 and memory die 104 (e.g., the same side of the die as terminals 106, 108). Silicon bridge 112 may be used to interconnect logic die 102 with memory die 104. Silicon bridge 112 may include a pattern of connection lines (e.g., circuitry or other line patterns). The pattern of connection lines may be designed to interconnect connections for active circuitry on logic die 102 with the appropriate (e.g., corresponding) connections for active circuitry on memory die 104.

In certain embodiments, silicon bridge 112 is a piece of silicon formed from a larger silicon wafer. For example, a silicon wafer may be processed (e.g, patterned) to form a plurality of patterns of connection lines with each pattern corresponding to an individual silicon bridge. The silicon wafer may then be separated (e.g., diced) to produce a plurality of silicon bridges with each bridge containing one pattern of connection lines. In some embodiments, silicon bridge 112 is a bridge made from a material other than silicon. For example, silicon bridge 112 may be a simple substrate bridge.

In certain embodiments, silicon bridge 112 is coupled to logic die 102 and memory die 104 with terminals 114. In certain embodiments, terminals 114 include solder interconnections. In some embodiments, terminals 114 include copper or gold interconnections. Terminals 114 may have a fine interconnect pitch (e.g., about 40 μm). In certain embodiments, terminals 114 are coupled to traces 115 (patterned connections) in silicon bridge 112. Traces 115 may have a very fine interconnect pitch. For example, traces 115 may have an interconnect trace pitch of at most about 1 μm. In some embodiments, traces 115 have an interconnect trace pitch of between about 0.5 μm and about 1 μm, between about 0.25 μm and about 1 μm, or between about 0.1 μm and about 1 μm.

After silicon bridge is coupled to logic die 102 and memory die 104, the logic die and the memory die (as well as silicon bridge 112) may be at least partially encapsulated in encapsulant 116, as shown in FIG. 4. Encapsulant 116 may be, for example, a polymer or a mold compound such as an overmold or exposed mold. In some embodiments, encapsulant 116 is overmolded over logic die 102, memory die 104, silicon bridge 112, and terminals 106, 108. Encapsulant 116 may fill the space between logic die 102 and memory die 104. Thus, encapsulant 116 may separate the side surfaces of logic die 102 and memory die 104. In some embodiments, encapsulant 116 is formed (applied to the structure) in multiple steps.

Encapsulant 116, as well as terminals 106, 108, may be subsequently grinded down or otherwise polished or planarized to expose portions of the terminals. In some embodiments, silicon bridge 112 is also grinded down when encapsulant 116 and terminals 106, 108 are grinded down. Grinding down silicon bridge 112 may reduce the thickness of the silicon bridge. In certain embodiments, silicon bridge 112 is grinded down to have a thickness of at most about 10 μm. In some embodiments, silicon bridge 112 has a thickness between about 5 μm and about 10 μm, between about 2.5 μm and about 15 μm, or between about 1 μm and about 20 μm.

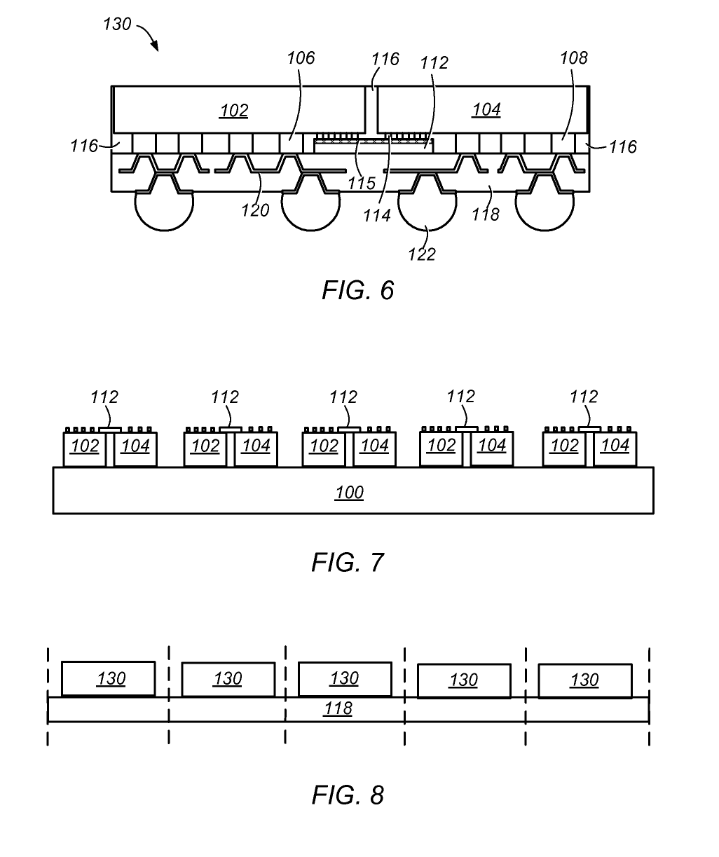

After encapsulation and subsequent grinding, carrier 110 is removed from the interconnected logic die 102 and memory die 104. FIG. 5 depicts a cross-sectional representation of logic die 102, memory die 104, and silicon bridge 112 in encapsulant 116. Encapsulant 116 may allow logic die 102, memory die 104, and silicon bridge 112 to be held together and allow the addition of redistribution layer (RDL) 118 to form package 130, as shown in FIG. 6. RDL 118 may include materials such as, but not limited to, PI (polyimide), PBO (polybenzoxazole), BCB (benzocyclobutene), and WPRs (wafer photo resists such as novolak resins and poly(hydroxystyrene) PHS) available commercially under the trade name WPR including WPR 1020, WPR-1050, and WPR-1201 (WPR is a registered trademark of JSR Corporation, Tokyo, Japan)). RDL 118 may be formed using techniques known in the art (e.g., techniques used for polymer deposition).

RDL 118 may include one or more layers of routing 120. In certain embodiments, RDL 118 includes two or more layers of routing 120. Routing 120 may be, for example, copper wiring or another suitable electrical conductor wiring that redistributes connections on one side of RDL 118 to another displaced (e.g., horizontally displaced) location on the other side of the RDL (e.g., the routing interconnects connections (terminals) on the top and bottom of the RDL that are horizontally offset). A thickness of RDL 118 may depend on the number of layers of routing 120 in the RDL. For example, each layer of routing 120 may be between about 5 μm and about 10 μm in thickness. In certain embodiments, RDL 118 may have a thickness of at least about 5 μm and at most about 50 μm.

In certain embodiments, as shown in FIG. 6, terminals 106 couple logic die 102 to routing 120 in RDL 118 and terminals 108 couple memory die 104 to the routing. Thus, RDL 118 is coupled to (e.g., directly attached to or directly in contact with) the active sides of logic die 102 and memory die 104. In certain embodiments, terminals 122 are coupled to routing 120 and RDL 118 in package 130. Terminals 122 may be coupled to logic die 102 and/or memory die 104 through routing 120 in RDL 118. Terminals 122 may include aluminum, copper, or another suitable conductive material. In some embodiments, terminals 122 are solder-coated or Sn-coated. In certain embodiments, terminals 122 form a ball grid array.

In package 130, logic die 102 and memory die 104 may be placed substantially adjacent (e.g., in a side-by-side configuration) to provide a high bandwidth memory to logic (e.g., SoC) interconnection using silicon bridge 112. Silicon bridge 112 may provide small path lengths (e.g., small or minimal trace connection length) between logic die 102 and memory die 104 with a high interconnect density (e.g., interconnect trace pitch of at most about 1 μm). The small path length and high interconnect density provides high bandwidth and low latency connection between logic die 102 and memory die 104. Additionally, locating silicon bridge 112 between the die and RDL 118 minimizes the overall thickness of package 130 to provide the package with a low profile. For example, package 130 may have a profile with a thickness of at most about 200 μm.

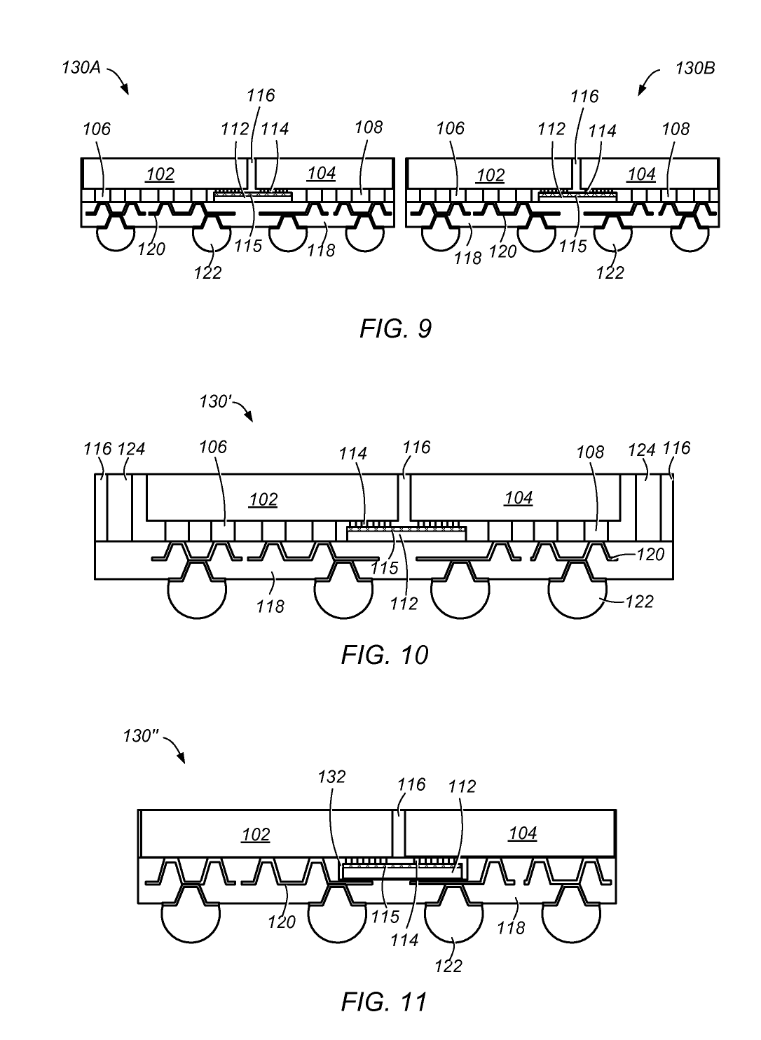

In certain embodiments, a plurality of packages 130 are formed simultaneously in a wafer level process. For example, carrier 100, shown in FIGS. 2-4, may be a wafer level carrier on which a plurality of logic die 102 and memory die 104 are coupled with silicon bridges 112, as shown in FIG. 7. The plurality of logic die 102 and memory die 104 (along with silicon bridges 112) on carrier 100 may be subject to subsequent processing according to the process flow in FIGS. 2-6 to form a plurality of packages 130 on a wafer level redistribution layer (e.g., RDL 118 may be a wafer level redistribution layer). FIG. 8 depicts a cross-sectional representation of an embodiment of a plurality of packages 130 formed on wafer level RDL 118. After forming packages 130 on RDL 118, the packages may be singulated (e.g., separated by dicing or cutting as shown by the dotted lines in FIG. 8) to form individual packages in their final format. FIG. 9 depicts a cross-sectional representation of an embodiment of two packages 130A, 130B formed using a wafer level process after singulation of the packages.

In certain embodiments, package 130 described herein is a discrete semiconductor device package. In some embodiments, the backside of logic die 102 and/or memory die 104 are encapsulated (e.g., the die are embedded or enclosed in encapsulant 116) to prevent exposure of the die to the surrounding environment. Encapsulating the backside of logic die 102 and/or memory die 104 protects the die when package 130 is used as a discrete package. In some embodiments, the backside of logic die 102 and/or memory die 104 include backside protection. The backside protection may be, for example, a fiber or resin designed to protect the backside of a wafer. The backside protection may be added either before or after formation of package 130.

In some embodiments, package 130 is used as a top or a bottom package in a PoP (“package-on-package”) package. When used in the PoP package, package 130 may include additional connections and/or terminals for use in the PoP package. For example, package 130 may include one or more vias (e.g., through-mold vias (TMVs)) through encapsulant 116. FIG. 10 depicts a cross-sectional representation of an embodiment of package 130′ with vias 124 through encapsulant 116. Vias 124 may be, for example, TMVs or other vias filled with conductive material (e.g., copper or solder). Package 130′ may be used as a bottom package in a PoP package with vias 124 being used to connect RDL 118 with terminals/connections in a top package. The top package may include, for example, additional memory to be used in the PoP package.

In some embodiments, the lower (active) surfaces of logic die 102 and memory die 104 in package 130 are directly contacted with RDL 118 without the use of terminal connections. FIG. 11 depicts a cross-sectional representation of an embodiment of semiconductor device package 130″ that includes logic die 102, memory die 104, silicon bridge 112, and RDL 118 with the silicon bridge in recess 132 in the RDL. In certain embodiments, terminals 106 and 108 are not formed on logic die 102 and memory die 104, and the lower (active) surfaces of the logic die and the memory die are directly attached to routing 120 in RDL 118 (e.g., the active surfaces are in direct contact with the routing). In such embodiments, recess 132 is formed in RDL 118 to accommodate silicon bridge 112. For example, recess 132 in RDL 118 may provide a volume for silicon bridge 112 to fit into and allow the lower surfaces of logic die 102 and memory die 104 to be directly coupled to the RDL.

Further modifications and alternative embodiments of various aspects of the embodiments described in this disclosure will be apparent to those skilled in the art in view of this description. Accordingly, this description is to be construed as illustrative only and is for the purpose of teaching those skilled in the art the general manner of carrying out the embodiments. It is to be understood that the forms of the embodiments shown and described herein are to be taken as the presently preferred embodiments. Elements and materials may be substituted for those illustrated and described herein, parts and processes may be reversed, and certain features of the embodiments may be utilized independently, all as would be apparent to one skilled in the art after having the benefit of this description. Changes may be made in the elements described herein without departing from the spirit and scope of the following claims.

What is claimed is:

1. A semiconductor device package, comprising:
a logic die at least partially encapsulated in an encapsulant;
a memory die at least partially encapsulated in the encapsulant, wherein the logic die is substantially adjacent to the memory die in the encapsulant;
a redistribution layer coupled to a lower surface of the logic die and a lower surface of the memory die; and
a silicon bridge interconnecting the logic die and the memory die, wherein the silicon bridge is coupled to the lower surfaces of the logic die and the memory die, and wherein the silicon bridge is located between the die and the redistribution layer.

2. The package of claim 1, wherein the logic die and the memory die are coupled to the redistribution layer in substantially adjacent positions.

3. The package of claim 1, wherein there is at least some encapsulant separating a side surface of the logic die and a side surface of the memory die.

4. The package of claim 1, wherein the logic die is coupled to the silicon bridge using a plurality of terminals coupled to traces in the silicon bridge, wherein the traces have an interconnect trace pitch of at most about 1 μm.

5. The package of claim 1, wherein the memory die is coupled to the silicon bridge using a plurality of terminals coupled to traces in the silicon bridge, wherein the traces have an interconnect trace pitch of at most about 1 μm.

6. The package of claim 1, wherein the lower surfaces of the logic die and the memory die comprise active surfaces of the die, and wherein the silicon bridge and the redistribution layer are directly attached to the active surfaces.

7. The package of claim 1, further comprising one or more terminals coupling the logic die and the memory die to the redistribution layer.

8. The package of claim 1, wherein the silicon bridge is located in a recess in the redistribution layer, and portions of the lower surfaces of the logic die and the memory die are in direct contact with routing in the redistribution layer.

9. A method for forming a semiconductor device package, comprising:
placing a logic die and a memory die substantially adjacent to each other on a carrier;
coupling a silicon bridge to the logic die and the memory die, wherien the silicon bridge interconnects the logic die and the memory die;
at least partially encapsulating the logic die, the memory die, and the silicon bridge in an encapsulant;
removing the carrier from the logic die and the memory die; and
coupling the logic die and the memory die to a redistribution layer.

10. The method of claim 9, further comprising coupling the silicon bridge to the logic die using a first set of terminals coupled to traces in the silicon bridge, and coupling silicon bridge to the memory die using a second set of terminals coupled to traces in the silicon bridge, wherein the traces in the silicon bridge have an interconnect trace pitch of at most about 1 μm.

11. The method of claim 9, wherein there is at least some space between the logic die and the memory die on the carrier, and wherein at least some encapsulant fills the space between the logic die and the memory die.

12. The method of claim 9, further comprising forming one or more terminals on the logic die and the memory die, and coupling the logic die and the memory die to the redistribution layer using the terminals.

13. The method of claim 12, wherein the terminals are formed on the logic die and the memory die before placing the die on the carrier.

14. The method of claim 9, further comprising forming a plurality of terminals on a surface of the redistribution layer opposite the logic die and the memory die, wherein at least one of the terminals is coupled to the logic die through routing in the redistribution layer, and wherein at least one of the terminals is coupled to the memory die through routing in the redistribution layer.

15. A semiconductor device package, comprising:
a redistribution layer;
a logic die coupled to a first surface of the redistribution layer and at least partially encapsulated in an encapsulant;
a memory die coupled to the first surface of the redistribution layer and at least partially encapsulated in the encapsulant, wherein the logic die is substantially adjacent to the memory die on the first surface of the redistribution layer; and
a silicon bridge interconnecting the logic die and the memory die, wherein the silicon bridge is located between the first surface of the redistribution layer and the die.

16. The package of claim 15, wherein the redistribution layer comprises a polymer with two or more layers of routing that redistributes connections on one side of the redistribution layer to another horizontally displaced location on the other side of the redistribution layer.

17. The package of claim 15, wherein the redistribution layer comprises a thickness between about 10 μm and about 50 μm.

18. The package of claim 15, wherein the silicon bridge has a thickness of at most about 10 μm.

19. The package of claim 15, wherein an upper surface of the logic die and an upper surface of the memory die are encapsulated in the encapsulant.

20. The package of claim 15, further comprising at least one terminal coupled to the redistribution layer through the encapsulant, wherein the terminal is configured to couple the redistribution layer to another semiconductor device package.
